(19) United States
(12) Patent Application Publication
(10) Pub. No.: US 2020/0068746 A1
(43) Pub. Date: Feb. 27, 2020

(54) THERMAL MATERIALS FOR INCREASING A RATE OF HEAT PIPE COOLING

(71) Applicant: GOOGLE LLC, Mountain View, CA (US)

(72) Inventors: James Juma, Fremont, CA (US); James Cooper, Sunnyvale, CA (US)

(21) Appl. No.: 16/111,356

(22) Filed: Aug. 24, 2018

(51) Int. Cl. H05K 7/20; F28F 21/02; G06F 1/20

(52) U.S. Cl. CPC H05K 7/20336; F28F 21/02; G06F 1/203; F28F 2013/001; H05K 7/20318; H05K 7/2039; H05K 7/20309

(57) ABSTRACT

Techniques of controlling heat from a heat source in an electronic device using a heat pipe, improved techniques include placing a thermal conductor such as graphite sheet in thermal contact with a heat pipe and an external surface such as a surface of a battery in an electronic device. In some implementations, the graphite sheet covers an area encompassing an end of the heat pipe. In some implementations, the graphite sheet is attached to the heat pipe using an adhesive.

### TECHNICAL FIELD

This description relates to heat transport within electronic devices.

### BACKGROUND

Electronic devices such as tablet computers generate a significant amount of heat. Typically, the heat generated by an electronic device is emitted out of the body of the device in the vicinity of the heat-generating mechanism (e.g., a CPU). To control this generated heat for the comfort of a user, heat pipes can be used to dissipate heat generated by a CPU.

A heat pipe is a heat-transfer device that combines the principles of both thermal conductivity and phase transition to effectively transfer heat between a heat source and a heat sink. At a hot interface of a heat pipe, a liquid in contact with a thermally conductive solid surface turns into a vapor by absorbing heat from that surface. The vapor then travels along the heat pipe to a cold interface and condenses back into a liquid, releasing latent heat. The liquid then returns to the hot interface through either capillary action, centrifugal force, or gravity, and the cycle repeats.

### SUMMARY

In one general aspect, an apparatus can include an enclosure and a heat source within the enclosure. The apparatus can also include a heat pipe within the enclosure, the heat pipe including (a) an evaporating portion in thermal contact with the heat source and at which heat is removed from the heat source to evaporate a liquid into a heated vapor and (b) a condensing portion at which the heated vapor is cooled back into the liquid. The apparatus can further include an external component located externally to the heat pipe and the heat source and within the enclosure. The apparatus can further include a thermal conductor in thermal contact with the heat pipe and a surface of the external component and in thermal contact with at least the heat pipe, the thermal conductor having a thermal conductivity greater than that of the surface of the external component.

In another general aspect, an electronic device can include a central processing unit (CPU). The electronic device can also include a heat pipe including (a) an evaporating portion in thermal contact with the heat source and at which heat is removed from the heat source to evaporate a liquid into a heated vapor and (b) a condensing portion at which the heated vapor is cooled back into the liquid. The electronic device can further include a graphite sheet in thermal contact with the condensing portion of the heat pipe.

The details of one or more implementations are set forth in the accompanying drawings and the description below. Other features will be apparent from the description and drawings, and from the claims.

### BRIEF DESCRIPTION OF THE DRAWINGS

FIG. 1A is a diagram that illustrates an example electronic device in which improved techniques described herein may be implemented.

FIG. 1B is a diagram that illustrates another example electronic device in which improved techniques described herein may be implemented.

FIG. 2A is a diagram that illustrates a top view of the other example electronic device.

FIG. 2B is a diagram that illustrates a cross-sectional view of the other example electronic device.

FIG. 3 is a diagram that illustrates another cross-sectional view of the other example electronic device.

FIG. 4 is a diagram that illustrates an example arrangement of a heat pipe and battery within the other example electronic device.

FIG. 5 illustrates an example of a computer device and a mobile computer device that can be used with circuits described here.

### DETAILED DESCRIPTION

Conventional techniques of controlling heat from a heat source in an electronic device using a heat pipe allow for an air gap between a heat pipe and battery. With such a heat gap, the condensation capability of the heat pipe (i.e., the rate at which the heat pipe converts heated vapor into condensed liquid) may not be sufficient to prevent the heated vapor from reaching an end of the heat pipe. Because the ends of the heat pipe are not good thermal conductors, the heat may flow back into the heat pipe, limiting the ability of the heat pipe to dissipate the heat from the CPU and potentially interfering with the user's experience.

In accordance with the implementations described herein and in contrast with the above-described conventional techniques of controlling heat from a heat source in an electronic device using a heat pipe, improved techniques include placing a thermal conductor such as graphite sheet in thermal contact with a heat pipe and an external surface such as a surface of a battery in an electronic device. In some implementations, the graphite sheet covers an area encompassing a condensing portion of the heat pipe. In some implementations, the graphite sheet is attached to the heat pipe using an adhesive.

Advantageously, the graphite sheet increases the condensing capability of the heat pipe. This in turn allows for heat to properly dissipate from the CPU. Further, the large surface area of the battery allows for further heat dissipation despite the low thermal conductivity of the battery surface.

In some implementations, the thermal conductor includes thermal grease and the external surface includes an enclosure of the electronic device.

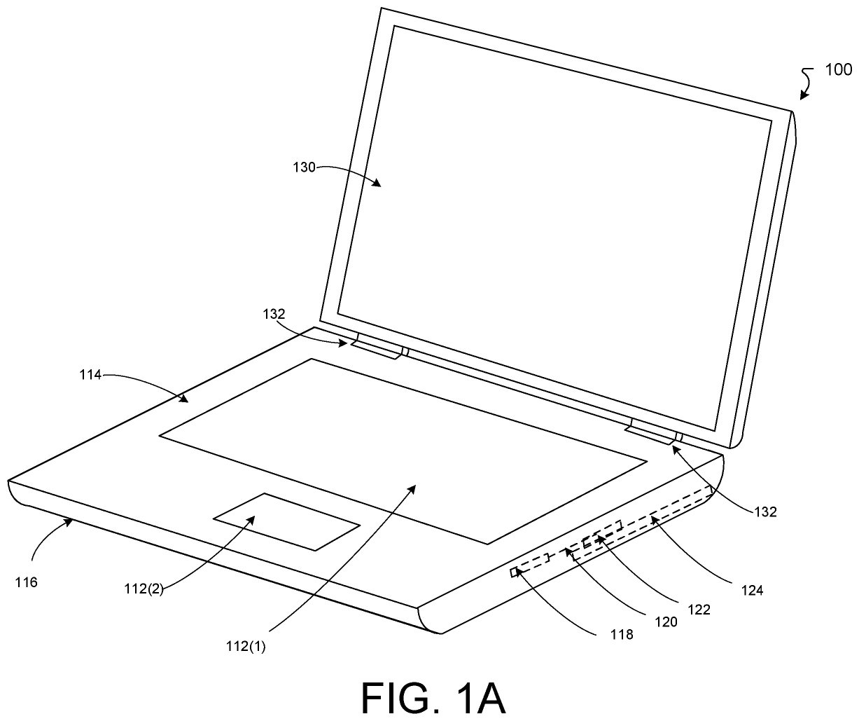

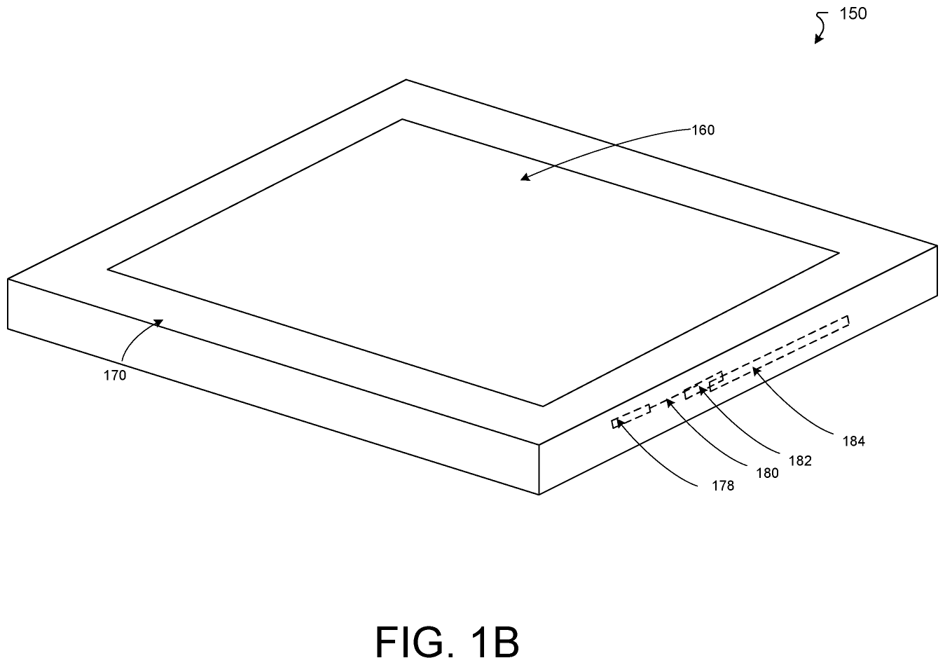

FIG. 1A is a diagram that illustrates a side view of an example electronic device, in this case a notebook computer 100 in which the above-described improved techniques may be implemented. As shown, in FIG. 1, the example notebook computer 100 includes a base portion 110, a monitor portion 130, and a hinge 132.

As shown in FIG. 1A, the base portion 110 provides the processing power that generates output to be displayed on the monitor portion 130. The base portion 110 includes a first external surface 114 and a second external surface 116.

In between these external surfaces 114 and 116, there is a heat source 118. In some implementations, the heat source 118 is a set of processing units. In some implementations, the set of processing units 118 includes a central processing unit (CPU). In some implementations, the set of processing units 118 includes a graphical processing unit (GPU). In some implementations, the set of processing units 118 includes other types of processors such as application-specific integrated circuits (ASICs), field-programmable gate arrays (FPGAs), and the like.

Depending on the type of processing units used in the set of processing units 118, as well as other factors such as clock speed, power consumption, etc., the set of processing units 118 produce a significant amount of heat within the base portion 110. Without a way to distribute the heat evenly over the surfaces 114 and 116, the notebook computer 100 may get too hot to operate unless the set of processing units 118 are not operated above a certain performance level (e.g., slower than 2.0 GHz clock speed). For example, an Intel® Core i7-920XM processor operating at 2.0 GHz is rated at 55 W of thermal design power (TDP). At this TDP rating, the maximum allowable temperature on the surfaces of a notebook computer are exceeded.

As shown in FIG. 1A, the base portion 110 also includes a heat pipe 120 and a battery 124. The heat pipe 120 is configured to dissipate heat generated by the set of processing units 118. As discussed above, to effect such dissipation, the heat pipe 120 has a liquid in contact with a thermally conductive (e.g., copper) surface, in which the liquid turns into a vapor by absorbing heat from that surface at an evaporating portion. The vapor then travels along the heat pipe to a condensing portion and condenses back into a liquid, releasing latent heat. The liquid then returns to the hot interface through either capillary action, centrifugal force, or gravity, and the cycle repeats.

The battery 124 provides electrical power to the notebook computer 100. In addition, the battery 100 can have surfaces that are poor electrical conductors (e.g., about 30 W/m/K). (W=Watt, m=meter, K=Kelvin unit of absolute temperature.) These surfaces can have large areas relative to surfaces of other components inside the notebook computer 100 (e.g., such a battery may have dimensions of about 50 mm×75 mm). Because of the large area of the battery 124 coupled with the poor thermal conductivity, the battery 124 provides a region over which the heat pipe 120 can terminate.

In a conventional electronic device, the heat pipe 120 is separated from the battery 124 by an air gap. As discussed above, the condensing capability of the heat pipe 120 may not be sufficient to cool the heat generated by the set of processing units 118 by the time the heated vapor generated from the set of processing units 118 reaches the end of the heat pipe in the vicinity of the battery 118. Because the end of the heat pipe 120 is not a good thermal conductor, the heated vapor that has not been cooled into liquid may be routed back into the heat pipe 120, building up excess heat in the heat pipe 120 and failing to dissipate properly.

To address this problem and as shown in FIG. 1A, the base portion 110 also includes a graphite sheet 122 between the heat pipe 120 and the battery 124. The graphite sheet 122 is in thermal contact with a surface of the heat pipe 120. The heat pipe 120 and the graphite sheet 122 can be considered to be in thermal contact when a heat transfer coefficient is greater than a threshold, e.g., 2000 W/m²/K. The heat transfer coefficient in thermodynamics is the proportionality constant between the heat flux and the thermodynamic driving force for the flow of heat (i.e., a temperature difference between the heat pipe 120 and the graphite sheet 122). In some implementations, the graphite sheet 122 is also in thermal contact with the battery 124.

The graphite sheet 122 is sized to cover an area of the heat pipe sufficient to induce a condensation rate increase sufficient to dissipate all of the heated vapor in the heat pipe 120. In some implementations, the graphite sheet 122 may have dimensions of 30 mm×10 mm. In some implementations in which the notebook computer 100 is smaller and accordingly generates more heat, the dimensions of the graphite sheet 122 may be larger, e.g., 40 mm×15 mm. In some implementations, the thickness of the graphite sheet 122 is between 0.01 mm and 0.1 mm. In some implementations, the thickness of the graphite sheet 122 is about 0.025 mm.

The graphite sheet 122 has a thermal conductivity that is greater than that of a surface of the battery 124 with which it is in thermal contact. For example, a typical value of the thermal conductivity of the graphite sheet 122 is about 1000 W/m/K. This is much greater than the 30 W/m/K that is associated with the surface of the battery 124.

By placing a thermal conductor like the graphite sheet 122 in thermal contact with a surface of the heat pipe 120 and a surface of the battery 124, the graphite sheet 122 is able to increase the condensing capability (i.e., the condensing rate) of the heat pipe 120. That is, the heat pipe 120 is able to convert heated vapor generated in the heat pipe 120 near the heat source (i.e., set of processing units 118) to cooled liquid at a rate faster than that when there is only an air gap between the heat pipe 120 and the battery 124. In this way, most, if not all, of the heat vapor is properly condensed into cool liquid and is dissipated as intended.

FIG. 1B is a diagram that illustrates a side view of another example electronic device, in this case a tablet computer 150. The tablet computer 150 includes a cover glass 160 and an enclosure 170.

Inside the enclosure 170, there is a heat source 178. In some implementations, the heat source 178 is a set of processing units. In some implementations, the set of processing units 178 includes a central processing unit (CPU).

Depending on the type of CPU used in the set of processing units 178, as well as other factors such as clock speed, power consumption, etc., the CPU 178 can produce a significant amount of heat within the enclosure 170. Without a way to distribute the heat evenly within the enclosure 170, the notebook computer 150 may get too hot to operate unless the CPU 178 is not operated above a certain performance level (e.g., slower than 2.0 GHz clock speed). For example, an ARM Cortex A-15 CPU operating at 2.5 GHz is rated at 8 W of thermal design power (TDP). At this TDP rating, a maximum allowable temperature on the surfaces of a tablet computer may be exceeded.

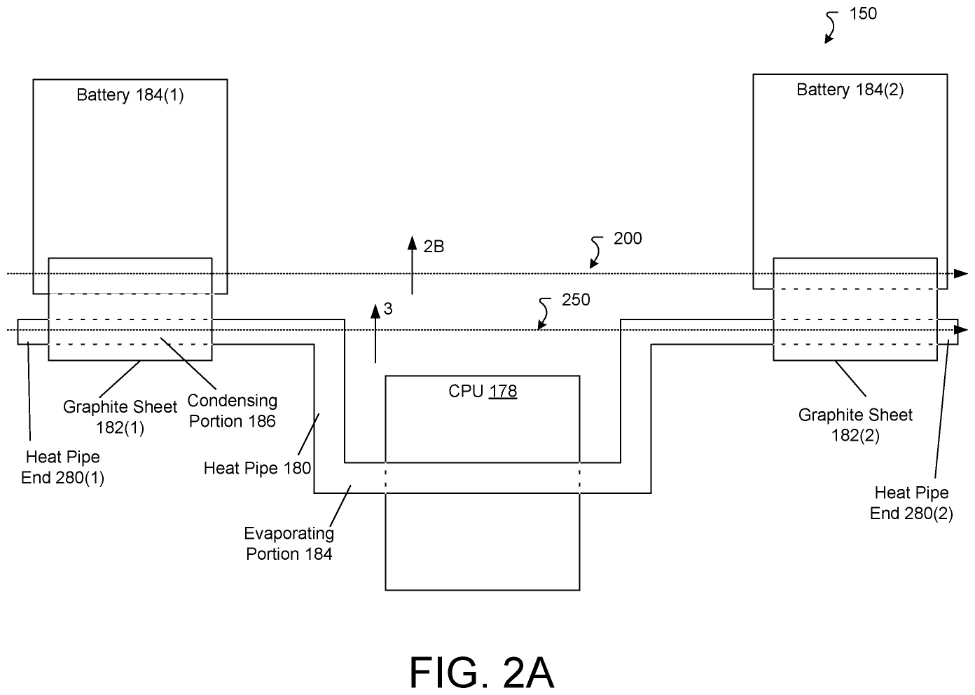

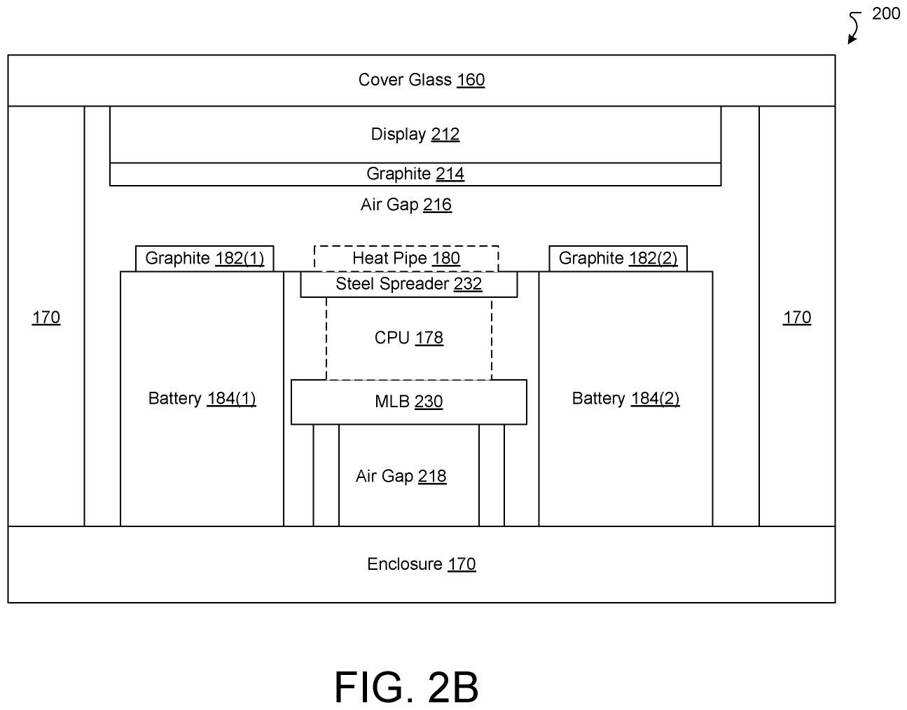

As shown in FIG. 1B, the tablet computer 150 also includes a heat pipe 180 and a battery 184 within the enclosure 170. As with the example notebook computer 100 discussed above, the tablet computer 150 also includes a graphite sheet 182 within the enclosure 170, between the heat pipe 180 and the battery 184. The graphite sheet 182 is in thermal contact with a surface of the heat pipe 180. The heat pipe 180 and the graphite sheet 182 can be considered to be in thermal contact when a heat transfer coefficient is greater than a threshold, e.g., 2000 W/m²/K. In some implementations, the graphite sheet 182 is also in thermal contact with the battery 184. Further details about the arrangement of the graphite sheet 182 within the enclosure are provided in FIGS. 2A and 2B.

FIG. 2A is a diagram illustrating a top view of the interior of the tablet computer 150. As shown in FIG. 2A, the tablet computer 150 includes a CPU 178, a heat pipe 180, graphite sheets 182(1) and 182(2), and batteries 184(1) and 184(2). In FIG. 2A, the dashed lines indicate an edge that is below an element of the drawing. For example, the graphite sheet 182(1) is above the battery 184(1) and the heat pipe 180, and the CPU 178 is also below the heat pipe 180.

As shown in FIG. 2A, the heat pipe 180 includes an evaporating portion 184 and a condensing portion 186. As discussed above, the heat pipe 120 has a liquid in contact with a thermally conductive (e.g., copper) surface, in which the liquid turns into a vapor by absorbing heat from that surface at the evaporating portion 184. The vapor then travels along the heat pipe to the condensing portion 186 and condenses back into a liquid, releasing latent heat. The liquid then returns to the hot interface either through capillary action, centrifugal force, or gravity, and the cycle repeats. As shown in FIG. 2A, the graphite sheet 182(1) covers an area encompassing the condensing portion 186 of the heat pipe 180.

As shown in FIG. 2A, the heat pipe 180 includes heat pipe ends 280(1) and 280(2). As discussed above, the heat pipe ends 280(1) and 280(2) have a high thermal resistance (e.g., the thermal conductivity is, in some implementations, between about 5 W/m/K and 10 W/m/K). Accordingly, the heat pipe ends 280(1) and 280(2) may get very hot if the condensing capability of the heat pipe 180 is not high enough. By placing the graphite sheets 182(1) and 182(2) between the heat pipe 180 at the condensing portion 186 and, respectively, the batteries 184(1) and 184(2), the heat pipe 180 is better able to dissipate heated vapor generated by the CPU 178.

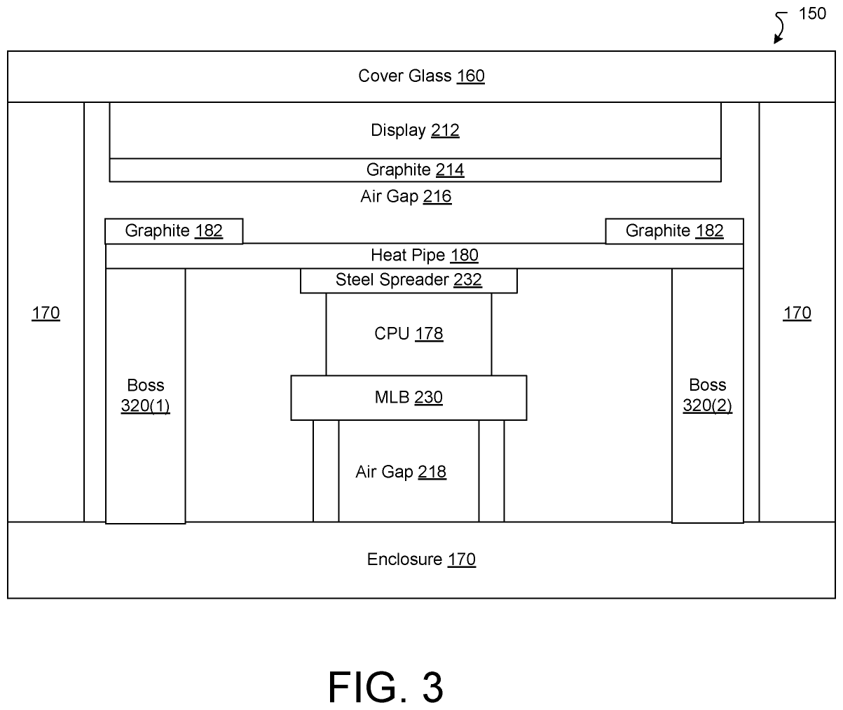

FIG. 2A also shows example cross-sections 200 and 250 of the tablet computer 150. The example cross-sections are labeled “2B” and “3” as they are illustrated in FIGS. 2B and 3, respectively.

FIG. 2B is a diagram illustrating a cross-sectional view 200 of the tablet computer 150. Again, the tablet computer 150 includes the cover glass 160 and the enclosure 170. As shown in FIG. 2B, the tablet computer 150 includes, within the enclosure 170, a pair of batteries 184(1) and 184(2) connected to the enclosure 170 at an end of the tablet computer 170 opposite that of the cover glass 160. In between the batteries and above the enclosure 170 to reveal an air gap 218 is a main logic board (MLB) 218. The MLB includes the CPU 178, as well as other components. A steel spreader 232 is located above the CPU 178 and the MLB 230 in general.

Also within the enclosure 170, attached to the cover glass 160, there are display electronics 212 that produce output seen by a user through the cover glass 160. On the other side of the display, a graphite element 214 is attached. Separated by an air gap 216 from the graphite element 214 is the heat pipe 180. In thermal contact with the heat pipe 180 and the batteries 184(1) and 184(2) are, respectively, graphite sheets 182(1) and 182(2). The heat pipe 180 and CPU 178 are shown with dashed lined because, according to FIG. 2A, they are slightly out of the plane shown in FIG. 2B.

In some implementations, the air gap 218 is between 0.2 mm and 0.8 mm. In some implementations, the air gap 218 is about 0.3 mm. In some implementations, the air gap 216 is between 0.6 mm and 1.0 mm. In some implementations, the air gap 216 is about 0.75 mm. In some implementations, the graphite sheets 182(1) and 182(2), as well as the graphite element 214, are between 0.01 mm and 0.1 mm thick. In some implementations, the graphite sheets 182(1) and 182(2) and the graphite element are about 0.025 mm thick. In some implementations, the heat pipe 180 is between 0.4 mm and 0.8 mm thick. In some implementations, the heat pipe 180 is about 0.6 mm thick.

FIG. 3 is a diagram illustrating another cross-sectional view 250 of the example tablet computer 150. As shown in FIG. 3, the heat pipe 180 extends out to a pair of bosses 320(1) and 320(2). The bosses 320(1) and 320(2) are associated with the batteries 184(1) and 184(2), respectively and, in some implementations, provide an external surface in thermal contact with the heat pipe 180. As shown in FIG. 3 and in some implementations, the bosses 320(1) and 320(2) are in physical contact with the heat pipe 180.

FIG. 3 also shows the graphite sheet 182 in two sections. This is due to the geometry of the heat pipe shown in FIG. 2A. The cross-sections of the heat pipe 182 shown in FIG. 3 are the left and right branches of the heat pipe 180 in the vicinity of the condensation portion 186.

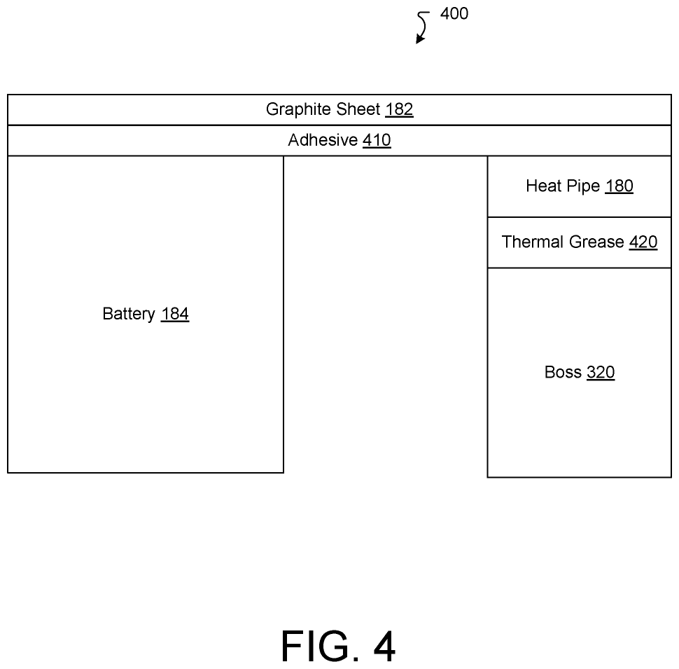

FIG. 4 is a diagram illustrating a detailed view 400 of an example technique of increasing the condensing capability of a heat pipe using additional thermal conductors. As shown in FIG. 4, the heat pipe 180 is attached to the graphite sheet 182 using an adhesive 410 applied along a surface of the heat pipe 180. In some implementations, the adhesive 410 includes a thermal conductor. In some implementations, the adhesive 410 includes a copper tape.

Also shown in FIG. 4 is a boss 420 associated with the battery 184. In the conventional approaches described above, the heat pipe 180 may be screwed down to the boss 420. In contrast and as shown in FIG. 4, the graphite sheet may be in thermal contact with the battery 184 via the adhesive 410.

Further shown in FIG. 4 is a thermal conductor—thermal grease 420—between the heat pipe 180 and the boss 420. In some implementations, the thickness of the thermal grease 420 is between 0.1 mm and 10 mm. In some implementations, the thickness of the thermal grease 420 is about 1 mm. As with the graphite sheet 182, the thermal grease provides additional condensing capability to the heat pipe 180.

In some implementations, the thermal grease 420 is the only thermal conductor in thermal contact with the heat pipe 180 and the boss 420. In some implementations, the battery is also in thermal contact with the ends of the heat pipe 180.

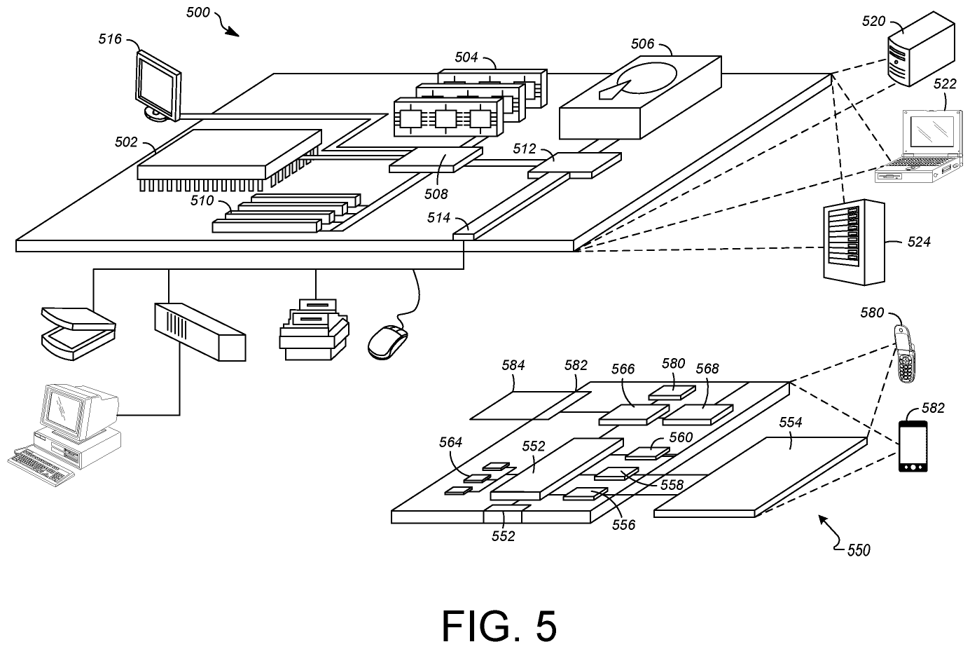

FIG. 5 illustrates an example of a generic computer device 500 and a generic mobile computer device 550, which may be used with the techniques described here.

As shown in FIG. 5, computing device 500 is intended to represent various forms of digital computers, such as laptops, desktops, workstations, personal digital assistants, servers, blade servers, mainframes, and other appropriate computers. Computing device 550 is intended to represent various forms of mobile devices, such as personal digital assistants, cellular telephones, smart phones, and other similar computing devices. The components shown here, their connections and relationships, and their functions, are meant to be exemplary only, and are not meant to limit implementations of the inventions described and/or claimed in this document.

Computing device 500 includes a processor 502, memory 504, a storage device 506, a high-speed interface 508 connecting to memory 504 and high-speed expansion ports 510, and a low speed interface 512 connecting to low speed bus 514 and storage device 506. Each of the components 502, 504, 506, 508, 510, and 512, are interconnected using various busses, and may be mounted on a common motherboard or in other manners as appropriate. The processor 502 can process instructions for execution within the computing device 500, including instructions stored in the memory 504 or on the storage device 506 to display graphical information for a GUI on an external input/output device, such as display 516 coupled to high speed interface 508. In other implementations, multiple processors and/or multiple buses may be used, as appropriate, along with multiple memories and types of memory. Also, multiple computing devices 500 may be connected, with each device providing portions of the necessary operations (e.g., as a server bank, a group of blade servers, or a multi-processor system).

The memory 504 stores information within the computing device 500. In one implementation, the memory 504 is a volatile memory unit or units. In another implementation, the memory 504 is a non-volatile memory unit or units. The memory 504 may also be another form of computer-readable medium, such as a magnetic or optical disk.

The storage device 506 is capable of providing mass storage for the computing device 500. In one implementation, the storage device 506 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 504, the storage device 506, or memory on processor 502.

The high speed controller 508 manages bandwidth-intensive operations for the computing device 500, while the low speed controller 512 manages lower bandwidth-intensive operations. Such allocation of functions is exemplary only. In one implementation, the high-speed controller 508 is coupled to memory 504, display 516 (e.g., through a graphics processor or accelerator), and to high-speed expansion ports 510, which may accept various expansion cards (not shown). In the implementation, low-speed controller 512 is coupled to storage device 506 and low-speed expansion port 514. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 500 may be implemented in a number of different forms, as shown in the figure. For example, it may be implemented as a standard server 520, or multiple times in a group of such servers. It may also be implemented as part of a rack server system 524. In addition, it may be implemented in a personal computer such as a laptop computer 522. Alternatively, components from computing device 500 may be combined with other components in a mobile device (not shown), such as device 550. Each of such devices may contain one or more of computing device 500, 550, and an entire system may be made up of multiple computing devices 500, 550 communicating with each other.

Computing device 550 includes a processor 552, memory 564, an input/output device such as a display 554, a communication interface 566, and a transceiver 568, among other components. The device 550 may also be provided with a storage device, such as a microdrive or other device, to provide additional storage. Each of the components 550, 552, 564, 554, 566, and 568, are interconnected using various buses, and several of the components may be mounted on a common motherboard or in other manners as appropriate.

The processor 552 can execute instructions within the computing device 550, including instructions stored in the memory 564. The processor may be implemented as a chipset of chips that include separate and multiple analog and digital processors. The processor may provide, for example, for coordination of the other components of the device 550, such as control of user interfaces, applications run by device 550, and wireless communication by device 550.

Processor 552 may communicate with a user through control interface 558 and display interface 556 coupled to a display 554. The display 554 may be, for example, a TFT LCD (Thin-Film-Transistor Liquid Crystal Display) or an OLED (Organic Light Emitting Diode) display, or other appropriate display technology. The display interface 556 may comprise appropriate circuitry for driving the display 554 to present graphical and other information to a user. The control interface 558 may receive commands from a user and convert them for submission to the processor 552. In addition, an external interface 562 may be provided in communication with processor 552, so as to enable near area communication of device 550 with other devices. External interface 562 may provide, for example, for wired communication in some implementations, or for wireless communication in other implementations, and multiple interfaces may also be used.

The memory 564 stores information within the computing device 550. The memory 564 can be implemented as one or more of a computer-readable medium or media, a volatile memory unit or units, or a non-volatile memory unit or units. Expansion memory 574 may also be provided and connected to device 550 through expansion interface 572, which may include, for example, a SIMM (Single In Line Memory Module) card interface. Such expansion memory 574 may provide extra storage space for device 550, or may also store applications or other information for device 550. Specifically, expansion memory 574 may include instructions to carry out or supplement the processes described above, and may include secure information also. Thus, for example, expansion memory 574 may be provided as a security module for device 550, and may be programmed with instructions that permit secure use of device 550. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 564, expansion memory 574, or memory on processor 552, that may be received, for example, over transceiver 568 or external interface 562.

Device 550 may communicate wirelessly through communication interface 566, which may include digital signal processing circuitry where necessary. Communication interface 566 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 568. In addition, short-range communication may occur, such as using a Bluetooth, WiFi, or other such transceiver (not shown). In addition, GPS (Global Positioning System) receiver module 570 may provide additional navigation- and location-related wireless data to device 550, which may be used as appropriate by applications running on device 550.

Device 550 may also communicate audibly using audio codec 560, which may receive spoken information from a user and convert it to usable digital information. Audio codec 560 may likewise generate audible sound for a user, such as through a speaker, e.g., in a handset of device 550. Such sound may include sound from voice telephone calls, may include recorded sound (e.g., voice messages, music files, etc.) and may also include sound generated by applications operating on device 550.

The computing device 550 may be implemented in a number of different forms, as shown in the figure. For example, it may be implemented as a cellular telephone 580. It may also be implemented as part of a smart phone 582, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing system can include clients and servers. A client and server are generally remote from each other and typically interact through a communication network. The relationship of client and server arises by virtue of computer programs running on the respective computers and having a client-server relationship to each other.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

1. An apparatus, comprising:
an enclosure,
a heat source within the enclosure,
a heat pipe within the enclosure, the heat pipe including (a) an evaporating portion in thermal contact with the heat source and at which heat is removed from the heat source to evaporate a liquid into a heated vapor and (b) a condensing portion at which the heated vapor is cooled back into the liquid, the heat pipe terminating at a first heat pipe end and a second heat pipe end, the liquid traveling away from the first heat pipe end and/or the second heat pipe end,
an external component located externally to the heat pipe and the heat source and within the enclosure, and
a thermal conductor in thermal contact with the heat pipe and a surface of the external component, the thermal conductor having a thermal conductivity greater than that of the surface of the external component.

2. The apparatus as in claim 1, wherein the thermal conductor includes a graphite sheet.

3. The apparatus as in claim 2, wherein the graphite sheet covers an area encompassing the condensing portion of the heat pipe.

4. The apparatus as in claim 2, wherein the graphite sheet is attached to the heat pipe using an adhesive.

5. The apparatus as in claim 4, wherein the adhesive includes a thermal conductor.

6. The apparatus as in claim 5, wherein the adhesive includes a copper tape.

7. The apparatus as in claim 1, wherein the heat source includes a central processing unit (CPU) of a computer.

8. The apparatus as in claim 7, wherein the external component includes a battery of the computer.

9. The apparatus as in claim 1, wherein the thermal conductor includes a sheet having a thickness of between 0.01 mm and 0.1 mm.

10. The apparatus as in claim 1, wherein the thermal conductor is in physical contact with both a lateral surface of the heat pipe and the surface of the external component.

11. An electronic device, comprising:
a central processing unit (CPU),
a heat pipe including (a) an evaporating portion in thermal contact with the heat source and at which heat is removed from the heat source to evaporate a liquid into a heated vapor and (b) a condensing portion at which the heated vapor is cooled back into the liquid, the heat pipe terminating at a first heat pipe end and a second heat pipe end, the liquid traveling away from the first heat pipe end and/or the second heat pipe end, and
a graphite sheet in thermal contact with the condensing portion of the heat pipe.

12. The electronic device as in claim 11, wherein the graphite sheet is attached to the heat pipe using an adhesive.

13. The electronic device as in claim 12, wherein the adhesive includes a thermal conductor.

14. The electronic device as in claim 13, wherein the adhesive includes a copper tape.

15. The electronic device as in claim 11, further comprising a battery, and
wherein the graphite sheet is also in thermal contact with a surface of the battery.

16. The electronic device as in claim 15, wherein electronic device includes a boss with which the thermal contact with a thermal conductor is established.

17. The electronic device as in claim 11, wherein a lateral surface of the heat pipe includes copper, and the liquid includes water.

18. The electronic device as in claim 11 wherein the graphite sheet has a thickness between 0.01 mm and 0.1 mm.

19. The apparatus as in claim 1, wherein the thermal conductivity of the thermal conductor is greater than a thermal conductivity of the first heat pipe end and the thermal conductivity of the second heat pipe end.

20. The apparatus as in claim 3, wherein the graphite sheet covers the area encompassing the condensing portion of the heat pipe on one side of the heat pipe.
